(19) United States
(12) Patent Application Publication
(10) Pub. No.: US 2014/0001637 A1
(43) Pub. Date: Jan. 2, 2014

(54) WIRING BOARD

(71) Applicant: KYOCERA SLC Technologies Corporation, Yasu-shi (JP)

(72) Inventors: Kohichi OHSUMI, Yasu-shi (JP); Yoshitaka SHIGA, Konan-shi (JP); Daichi OHMAE, Kusatsu-shi (JP)

(21) Appl. No.: 13/929,238

(22) Filed: Jun. 27, 2013

(30) Foreign Application Priority Data
Jun. 29, 2012 (JP) 2012-146360
Aug. 28, 2012 (JP) 2012-187676

(51) Int. Cl. H01L 23/498

(52) U.S. Cl. CPC H01L 23/49822
USPC 257/766

(57) ABSTRACT

A wiring board in which a semiconductor element connection pad formed on a strip-shaped wiring conductor and an electrode of a semiconductor element are firmly connected together, the wiring board having excellent electrical insulation between the semiconductor element connection pads which are adjacent to each other.

### BACKGROUND OF THE INVENTION

1. Field of the Invention

The present invention relates to a wiring board for mounting a semiconductor element or the like.

2. Description of Related Art

FIGS. 3(a) and 3(b) illustrate a conventional wiring board 20 for mounting thereon a semiconductor element such as a semiconductor integrated circuit element as described in Japanese Unexamined Patent Application Publication No. 2010-206192. As illustrated in FIGS. 3(a) and 3(b), the wiring board 20 has an insulating board 11 having a mounting portion 11a which is provided in a center of an upper surface thereof for mounting a semiconductor element S, and a plurality of through-holes 11b which are provided in a peripheral portion thereof in a manner to penetrate from upper surface to lower surface of the insulating board 11; a plurality of wiring conductors 12 adhered to upper and lower surfaces of the insulating board 11 and inside the through holes 11b; and a solder resist layer 13 adhered to the upper and lower surfaces of the insulating board 11. The insulating board 11 and the solder resist layer 13 are made of, for example, a resin insulating material including a thermosetting resin such as an epoxy resin. In addition, the wiring conductor 12 is made of copper.

The wiring conductor 12 adhered to the upper surface of the insulating board 11 includes a plurality of strip-shaped wiring conductors 14. These strip-shaped wiring conductors 14 are arranged side by side and perpendicular to an outer periphery of the semiconductor element S in an outer peripheral portion of the mounting portion 11a. The strip-shaped wiring conductors 14 are partially exposed inside slit-like openings 13a provided in the solder resist layer 13 in the outer peripheral portion of the mounting portion 11a. Further, a semiconductor element connection pad 15 in a protruding shape is formed on each of the strip-shaped wiring conductors 14 which are exposed inside the openings 13a. The semiconductor element connection pad is a connecting terminal for connecting the semiconductor element S to the strip-shaped wiring conductors 14. An electrode T of the semiconductor element S is connected to the semiconductor element connection pad 15 through solder, so that the semiconductor element S and the strip-shaped wiring conductor 14 are electrically connected together. Since the semiconductor element connection pad 15 is protruding, an appropriate gap is formed between the wiring board 20 and the semiconductor element S.

The wiring conductor 12 adhered to the lower surface of the insulating board 11 includes a plurality of external connection pads 16. Each of the external connection pads is circular, and is exposed through the opening 13a provided in the solder resist layer 13 on a side of the lower surface. The external connection pad 16 is electrically connected to an external electric circuit board through solder. Then, the electrode T of the semiconductor element S is connected to the semiconductor element connection pad 15, and the external connection pad is connected to a wiring conductor of the external electric circuit board, so that the semiconductor element S is electrically connected to the external electric circuit board. As a result, a signal is transmitted through the wiring conductor 12 between the semiconductor element S and the external electric circuit board, and the semiconductor element S operates.

In the meantime, when the electrode T of the semiconductor element S is connected to the semiconductor element connection pad 15, a well-known flip-chip technology is preferably used. Specifically, for example, solder is welded in advance to each of the semiconductor element connection pads 15, and each of the electrodes T of the semiconductor element S is placed on the corresponding solder. Thereafter, the solder is melted by a reflow process, cooled, and fixed to the electrode T, so that the electrode T and the semiconductor element connection pad 15 are connected together.

However, according to the conventional wiring board 20, the strip-shaped wiring conductor 14 and the semiconductor element connection pad 15 thereon are both made of copper which is excellent in solder wettability. For this reason, when the reflow process is applied, the molten solder becomes wet and may spread in a wide area not only on the semiconductor element connection pad 15 but also on an exposed surface of the strip-shaped wiring conductor 14. As a result, the solder becomes insufficient for connecting the electrode T of the semiconductor element S and the semiconductor element connection pad 15 to each other, which may cause a case where the electrode T and the semiconductor element connection pad 15 are not firmly connected together. Further, the molten solder flows around on a side surface of each of the semiconductor element connection pads 15, which may cause a gap between the solders on the adjacent semiconductor element connection pads 15 to become narrow, or the solders to make contact with each other. As a result, electrical insulation between the adjacent semiconductor element connection pads 15 may be impaired.

### BRIEF SUMMARY OF THE INVENTION

It is an object of the present invention to provide a wiring board in which a semiconductor element connection pad formed on a strip-shaped wiring conductor and an electrode of a semiconductor element are firmly connected together, the wiring board having excellent electrical insulation between the semiconductor element connection pads which are adjacent to each other.

A wiring board according to the present invention is provided with: an insulating board having , on an upper surface thereof, a mounting portion in which a semiconductor element is mounted; a plurality of strip-shaped wiring conductors arranged side by side on the upper surface of the insulating board, and extending in an outer peripheral portion of the mounting portion in a manner to be perpendicular to an outer periphery of the semiconductor element; a semiconductor element connection pad formed, on each of the strip-shaped wiring conductors, in a protruding shape and in a width identical with a width of the strip-shaped wiring conductor; and a solder resist layer adhered to the upper surface of the insulating board, and having a slit-like opening along the outer periphery of the semiconductor element, so that the semiconductor element connection pad and a part of the strip-shaped wiring conductor are partially exposed in the slit-like opening, in which the semiconductor element connection pad is formed of a first conductor layer which is adhered onto the strip-shaped wiring conductor and has poor solder wettability, and a second conductor layer which is adhered onto an upper surface of the first conductor layer and has solder wettability.

According to the wiring board of the present invention, the semiconductor element connection pad on the strip-shaped wiring conductor is formed of the first conductor layer which is adhered onto the strip-shaped wiring conductor so that a side surface thereof is exposed and has poor solder wettability, and a second conductor layer which is adhered onto the first conductor layer and has solder wettability. Accordingly, during the reflow process when the semiconductor element is mounted by the flip-chip technology, the molten solder becomes wet and spreads out on the surface of the second conductor layer which is provided on an upper surface of the semiconductor element connection pad and is superior in solder wettability. In contrast, the first conductor layer which has poor solder wettability is formed with a side surface thereof exposed under the second conductor layer. Therefore, the molten solder exhibits poor wettability and does not spread with respect to the side surface of the semiconductor element connection pad and the strip-shaped wiring conductor located thereunder. As a result, the molten solder can be held on the semiconductor element connection pad, and can be prevented from flowing around the side surface of the semiconductor element connection pad. Accordingly, it is possible to provide the wiring board in which the electrode of the semiconductor element and the semiconductor element connection pad are firmly connected together through a necessary amount of solder, the wiring board having excellent electrical insulation between the semiconductor element connection pads which are adjacent to each other.

### BRIEF DESCRIPTION OF THE DRAWINGS

FIGS. 1(a) and 1(b) are a schematic sectional view and a plan view, respectively, illustrating an embodiment of a wiring board according to the present invention.

FIG. 2 is an enlarged cross sectional view of a principal portion of the wiring board illustrated in FIGS. 1(a) and 1(b).

FIGS. 3(a) and 3(b) are a schematic sectional view and a plan view, respectively, illustrating one example of a conventional wiring board.

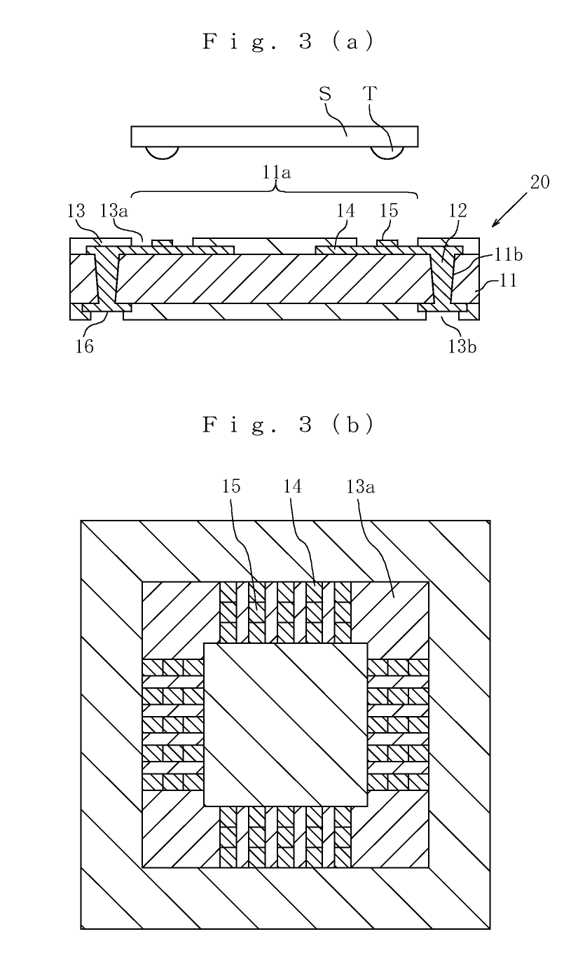

### DETAILED DESCRIPTION OF EXEMPLARY EMBODIMENTS

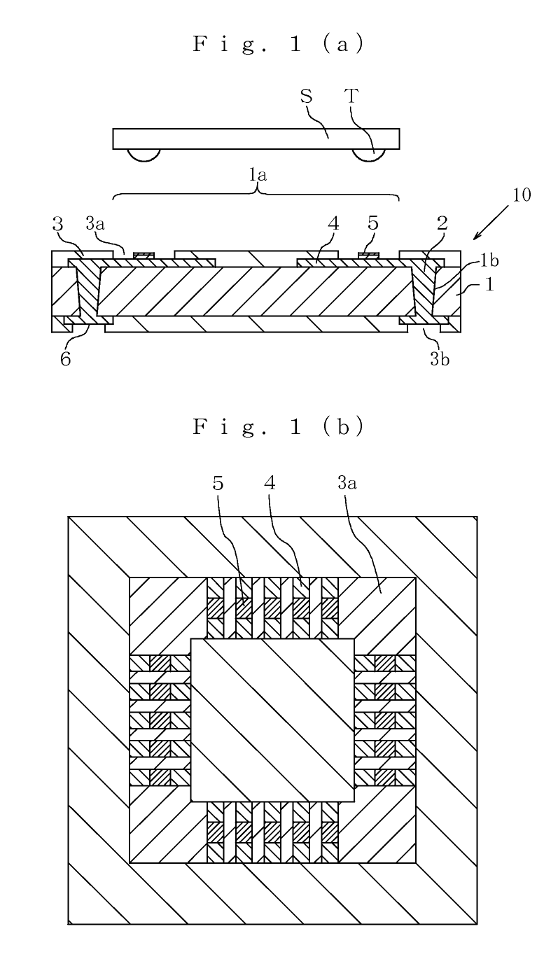

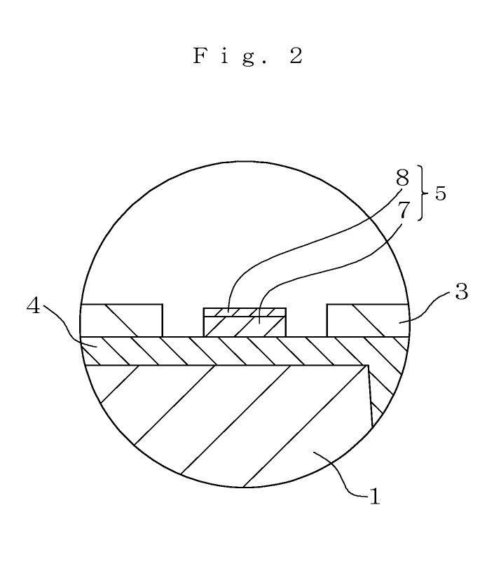

Next, an embodiment of a wiring board according to the present invention will be described with reference to FIGS. 1(a), 1(b), and 2. As illustrated in FIG. 1(a), a wiring board 10 according to the present invention provides mainly an insulating board 1, a wiring conductor 2, and a solder resist layer 3.

The insulating board 1 is made of an electric insulating material obtained by impregnating glass cloth with a thermosetting resin such an epoxy resin or a bismaleimide triazine resin. Although the insulating board 1 has a single-layer structure in FIG. 1(a), the insulating board 1 may have a multilayer structure formed by laminating a plurality of insulating layers made of identical electric insulating material or different electric insulating materials. A thickness of the insulating board 1 is preferably about 100 to 200 μm.

The insulating board 1 has a mounting portion 1a which is provided in a center of an upper surface thereof for mounting a semiconductor element S, and a plurality of through-holes 1b which are provided in a peripheral portion thereof in a manner to penetrate from upper surface to lower surface of the insulating board 1 vertically. The mounting portion la has a size and a shape corresponding to those of the semiconductor element S. A lower surface of the insulating board 1 serves as a connection surface for connecting to an external electric circuit board. A wiring conductor 2 is adhered to the upper and lower surfaces of the insulating board 1 and inside the through-holes 1b.

The wiring conductors 2 are made of copper such as copper foil or copper plating. Each of the wiring conductors 2 adhered to the upper surface of the insulating board 1 includes a strip-shaped wiring conductor 4. These strip-shaped wiring conductors 4 are arranged side by side and extending perpendicular to an outer periphery of the semiconductor element S in an outer peripheral portion of the mounting portion 1a. The strip-shaped wiring conductors 4 are partially exposed inside slit-like openings 3a provided in the solder resist layer 3 in the outer peripheral portion of the mounting portion 1a. Further, a semiconductor element connection pad 5 in a protruding shape is formed on each of the strip-shaped wiring conductors 4 which are exposed inside the openings 3a.

The wiring conductor 2 adhered to the lower surface of the insulating board 1 includes a plurality of external connection pads 6 for connecting to an external electric circuit board. Each of the external connection pads 6 is circular, and is exposed through the opening 3b provided in the solder resist layer 3 on a side of the lower surface. Here, the solder resist layer 3 is made of an electric insulating material obtained by curing a thermosetting resin such as an acrylic modified epoxy resin having photosensitivity.

Then, an electrode T of the semiconductor element S is connected to the semiconductor element connection pad 5 by the flip-chip technology, and the external connection pad 6 is connected to a wiring conductor of the external electric circuit board, so that the semiconductor element S is electrically connected to the external electric circuit board. As a result, a signal is transmitted through the wiring conductor 2 between the semiconductor element S and the external electric circuit board, and the semiconductor element S operates. The wiring conductor 2 is formed by a well-known subtractive process or semi-additive process. The strip-shaped wiring conductor 4 has a width of preferably about 10 to 30 μm, and a thickness of preferably about 10 to 20 μm.

As illustrated in FIG. 1(b), the semiconductor element connection pad 5 is arranged in a manner to correspond to the electrode T of the semiconductor element S. Referring to FIG. 1(b), the semiconductor element connection pads 5 are individually arranged side by side on the strip-shaped wiring conductors 4 which are exposed in the slit-like openings 3a. Referring to FIGS. 1(a), 1(b), and 2, a width of the semiconductor element connection pad 5 is identical with the width of the strip-shaped wiring conductor 4. The semiconductor element connection pad 5 has a length of preferably about 40 to 60 μm, and a height of preferably about 2.5 to 11 μm.

As illustrated in FIG. 2, the semiconductor element connection pad 5 is formed of a first conductor layer 7 and a second conductor layer 8 which are sequentially adhered to the strip-shaped wiring conductor 4. According to the wiring board of the present invention, it is preferable that the first conductor layer 7 is thicker than the second conductor layer 8. By such a constitution, the molten solder becomes difficult to get wet and spread out on the strip-shaped wiring conductor 4 over a side of the first conductor layer 7.

The first conductor layer 7 is made of a metal having low solder wettability (i.e., poor in solder wettability) such as nickel or chrome. A thickness of the first conductor layer 7 is preferably about 2 to 10 μm, and a side surface thereof is not covered with the second conductor layer 8 but is exposed. If the thickness of the first conductor layer 7 is too thin, the molten solder tends to become easy to get wet and spread out on the strip-shaped wiring conductor 4 over the side of the first conductor layer 7. The second conductor layer 8 is made of a metal having solder wettability (superior to the solder wettability of the first conductor layer 7) such as gold or palladium. A thickness of the second conductor layer 8 is preferably 0.3 to 1 μm, and covers only an upper surface of the first conductor layer 7. If the thickness of the second conductor layer 8 is too thick, a metal forming the second conductor layer 8 spreads to the solder and many brittle intermetallic compounds become easy to be formed when the solder is molten. Therefore, a connection strength of the solder may become poor.

As described above, according to the wiring board of the present invention, the semiconductor element connection pad 5 on the strip-shaped wiring conductor 4 is formed of the first conductor layer 7 which is adhered onto the strip-shaped wiring conductor 4 and has poor solder wettability, and the second conductor layer 8 which is adhered onto the upper surface of the first conductor layer 7 and has solder wettability. For this reason, during the reflow process when the semiconductor element S is mounted by the flip-chip technology, the molten solder becomes wet and spreads out on the surface of the second conductor layer 8 which is an upper surface of the semiconductor element connection pad 5 and is superior in solder wettability. In contrast, the first conductor layer 7 which has poor solder wettability is formed with a side surface thereof exposed under the second conductor layer 8. Therefore, the molten solder exhibits poor wettability and does not spread with respect to the side surface of the semiconductor element connection pad 5 and the strip-shaped wiring conductor 4 located thereunder. As a result, the molten solder can be held on the semiconductor element connection pad 5, and can be prevented from flowing around the side surface of the semiconductor element connection pad 5. Accordingly, it is possible to provide the wiring board 10 in which the electrode T of the semiconductor element S and the semiconductor element connection pad 5 are firmly connected together through a necessary amount of solder, and which has excellent electrical insulation between the semiconductor element connection pads 5 which are adjacent to each other.

The semiconductor element connection pad 5 can be formed, for example, through the following procedures (1) to (6).

(1) Electroless copper plating is adhered to the surface of the insulating board 1.

(2) A first plating resist layer having a first opening portion corresponding to a pattern of the strip-shaped wiring conductor 4 is formed on the electroless copper plating.

(3) A copper electroplating layer serving as the strip-shaped wiring conductor 4 is formed on the electroless copper plating exposed from the first opening portion.

(4) A second plating resist layer having a second opening portion that crosses the first opening portion is formed on the first plating resist layer and the copper electroplating, so that a copper plating layer in a position in which the semiconductor element connection pad 5 is formed is exposed for the amounts of a width and a length that are identical with those of the semiconductor element connection pad 5.

(5) After a nickel electroplating layer is deposited on the copper plating layer that is exposed from the first and second opening portions, an electrolytic gold plating layer is further deposited thereon.

(6) After the second plating resist and the first plating resist are exfoliated and removed, exposed portion of the electroless copper plating is removed by etching, so that the semiconductor element connection pad 5 is formed on the strip-shaped wiring conductor 4.

The present invention is not limited to the embodiment described above, and various modifications may be made within a scope without departing from the spirits of the present invention. For example, in the embodiment described above, an oxide film having poor wettability may be formed on at least the surface of the strip-shaped wiring conductor 4 that is exposed in the opening 3a. By forming the oxide film, during the reflow process when the semiconductor element S is mounted by the flip-chip technology, it is possible to further reliably restrain the molten solder from becoming wet and spreading over the surface of the strip-shaped wiring conductor 4. It is preferable to use a black oxide treatment for the oxide film. The black oxide treatment is for forming needle crystal of copper oxide having a length of about 0.2 to 0.5 iim on a surface of copper. By performing such a black oxide treatment, it is extremely effective for suppressing the wetting and spreading of the molten solder. Such a black oxide treatment is performed, for example, as described below. First, the processes up to removing the electroless copper plating by etching are performed following the above-mentioned procedure for forming the semiconductor element connection pad 5. Next, by immersing the strip-shaped wiring conductor 4 on which the semiconductor element connection pad 5 is formed in a sodium chlorite solution, so that the needle crystal by the black oxide treatment is formed on the surface of the strip-shaped wiring conductor 4.

What is claimed is:

1. A wiring board comprising:
an insulating board having, on an upper surface thereof, a mounting portion in which a semiconductor element is mounted;
a plurality of strip-shaped wiring conductors arranged side by side on the upper surface of the insulating board, and extending in an outer peripheral portion of the mounting portion in a manner to be perpendicular to an outer periphery of the semiconductor element;
a semiconductor element connection pad formed, on each of the strip-shaped wiring conductors, in a protruding shape and in a width identical with a width of the strip-shaped wiring conductor; and
a solder resist layer adhered to the upper surface of the insulating board, and having a slit-like opening along the outer periphery of the semiconductor element, so that the semiconductor element connection pad and a part of the strip-shaped wiring conductor are exposed in the slit-like opening,
wherein the semiconductor element connection pad is formed of a first conductor layer which is adhered onto the strip-shaped wiring conductor and has poor solder wettability, and a second conductor layer which is adhered onto an upper surface of the first conductor layer and has solder wettability.

2. The wiring board according to claim 1,
wherein the first conductor layer is made of nickel or chrome, and
the second conductor layer is made of gold or palladium.

3. The wiring board according to claim 2,
wherein the first conductor layer and the second conductor layer are plating layers.

4. The wiring board according to claim 1,
wherein an oxide film is formed on at least a surface of the strip-shaped wiring conductor that is exposed in the opening.

5. The wiring board according to claim 1,
wherein a thickness of the first conductor layer is larger than a thickness of the second conductor layer.

6. The wiring board according to claim 5
wherein the thickness of the first conductor layer is 2 to 10 μm, and
the thickness of the second conductor layer is 0.3 to 1 μm.
